(19) United States
(12) Patent Application Publication
(10) Pub. No.: US 2012/0012159 A1
(43) Pub. Date: Jan. 19, 2012

(54) Solar cell module and method for manufacturing the solar cell module, and mobile device with the solar cell module and method for manufacturing the mobile device

(75) Inventors: Jin Mun Ryu, Hwaseong-si (KR); In Taek Song, Seongnam-si (KR); Tae Young Kim, Seoul (KR); Seung Yun Oh, Suwon-si (KR)

(73) Assignee: Samsung Electro-Mechanics Co., Ltd., Suwon (KR)

(21) Appl. No.: 12/926,409

(22) Filed: Nov. 16, 2010

(30) Foreign Application Priority Data
Jul. 14, 2010 (KR) 10-2010-0067964

(51) Int. Cl. H01L 31/048; H01L 31/18

(52) U.S. Cl. 136/251; 438/66; 257/E31.113

(57) ABSTRACT

The present invention provides a solar cell module. The solar cell module includes a floodlight panel with a light transmission property; solar cells each of which has a light-receiving surface with electrode pads and a non-light-receiving surface opposite to the light-receiving surface, the solar cells being adhered to the floodlight panel so that the light-receiving surface faces the floodlight panel; and a conductive bonding film which is interposed between the floodlight panel and the solar cells and bonds the floodlight panel to the solar cells, wherein the conductive bonding film is used to electrically connect the electrode pads of the solar cells adjacent to one another.

### CROSS-REFERENCE TO RELATED APPLICATIONS

This application claims the benefit of Korean Patent Application No. 10-2010-0067964 filed with the Korea Intellectual Property Office on Jul. 14, 2010, the disclosure of which is incorporated herein by reference.

### BACKGROUND OF THE INVENTION

1. Field of the Invention

The present invention relates to a solar cell module and a mobile device equipped with the solar cell module; and, more particularly, to a solar cell module with a higher degree of integration and light-transmissive rate, a mobile device equipped with the solar cell module, and methods for manufacturing the solar module and the mobile device.

2. Description of the Related Art

In general, the electrodes of a silicon solar cell may be divided into a front surface electrode and a rear surface electrode depending on their structures. A solar cell module with the front and rear electrodes may usually have a solar cell junction structure of a chip on board (COB) scheme or a chip on glass (COG) scheme.

FIG. 1 is a view showing one example of a mobile device equipped with a solar cell module in the prior art. Referring to FIG. 1, the mobile device 10 may be provided with a case 20, and a solar cell module 30 embedded in the case 20. One side of the case 20 may be provided with a transparent glass 22 through which light can be incident on the solar cell module 30. The other side of the case 20 may be provided with a display unit 24 for displaying information to the outside.

The solar cell module 30 may be attached on the transparent glass 22 in such a manner that its light-receiving surface is opposite to the transparent glass 22. The solar cell module 30 may have such a structure as a solar cell module of the COB scheme or the BOG scheme. For example, the solar cell module 30 may include a Printed Circuit Board (PCB) 32, elements of solar cells (hereinafter, referred to as “solar cells 34”) attached on one surface of the PCB, bonding wires 36 for connection of the solar cells 34 to the PCB 32, and a transparent molding film 38 for covering these components.

In the mobile device with the above-described structure, when external light is incident on the solar cells 34 after passing through the transparent glass 22, and the transparent molding film in order. In this case, since a certain adhesive is interposed between the transparent glass 22 and the transparent molding film 38, the external light may be substantially suffered from light-loss in the course of at least three steps. Thus, the mobile device 10 may have a structure with low light-transmissive rates to the solar cells 34. The loss of the incident light may occur in the middle of passage of the transparent molding film 38. That is, in case where the transparent molding film 38 made of a transparent epoxy resin is used, there has been a problem that the light-transmissive rate of the incident light is reduced to 90% or lower.

In addition, there is a limit to integration of the solar cells 34 with the above-described structure. For example, a total thickness of the solar cells 34 is obtained by summing respective thicknesses of the PCB 32, the solar cells 34, and the transparent molding film 38. However, since the solar cells 34 with the above-mentioned structure have difficulty improving a much more degree of integration, they fail to meet the recent demand for a degree of integration of a solar cell module.

Also, since such solar cells 34 have a structure of using the bonding wire 36, there is a need to have a space for formation of the bonding wire 36. However, when the bonding wire 36 is used, a relatively large space is required for bending it, so there is a limit to improvement of a degree of integration for the solar cells 34.

### SUMMARY OF THE INVENTION

The present invention has been proposed in order to overcome the above-described problems and it is, therefore, an object of the present invention to provide a solar cell module for improving a light-transmissive rate and a mobile device equipped with the solar cell module.

Further, another object of the present invention is to provide a solar cell module for improving a degree of integration, and a mobile device equipped with the solar cell module.

Further, another object of the present invention is to provide a method for manufacturing a solar cell module with an improved light-transmissive rate and a method for manufacturing a mobile device equipped with the solar cell module.

Further, another object of the present invention is to provide a method for manufacturing a solar cell module with an improved degree of integration and a method for manufacturing a mobile device equipped with the solar cell module.

In accordance with one aspect of the present invention to achieve the object, there is provided a solar cell module including: a floodlight panel with a light transmission property; solar cells each of which has a light-receiving surface with electrode pads and a non-light-receiving surface opposite to the light-receiving surface, the solar cells being adhered to the floodlight panel so that the light-receiving surface faces the floodlight panel; and a conductive bonding film which is interposed between the floodlight panel and the solar cells and bonds the floodlight panel to the solar cells, wherein the conductive bonding film is used to electrically connect the electrode pads of the solar cells adjacent to one another.

Also, the conductive bonding film is formed by coating a metal paste composition on the floodlight panel.

Also, the conductive bonding film corresponds to a metal film including at least one of Au, Ag, Ni, In, Zn, Ti, Cu, Cr, Ta, W, Pt, Fe, and Co.

Also, the conductive bonding has one end connected to a plus electrode pad of any one in solar cells, and the other end connected to a minus electrode pad of the other solar cell adjacent to the one solar cell.

Also, the floodlight panel has an exposure surface exposed to the outside, and a non-exposure surface facing the light-receiving surface of the solar cells, and the solar cell module further includes a molding film for covering the non-exposure surface so that the solar cells can be made airtight.

Also, the module further includes a conductive spacer which is interposed between the floodlight panel and the solar cells and maintains intervals between the floodlight panel and the solar cells to be preset intervals.

Also, the molding film is formed of an opaque material.

Also, the conductive module is bonded to the electrode pads.

Also, the conductive spacer is made of at least one metal of Au, Ag, Ni, In, Zn, Ti, Cu, Cr, Ta, W, Pt, Fe, and Co.

Also, the conductive spacer further includes a stud bump.

In accordance with other aspect of the present invention to achieve the object, there is provided a mobile device including: a case which has one side with openings; a display unit which is formed on the other side of the case and displays information to the outside; and a solar cell module which is embedded in the case and receives external light to convert the received external light into an electric energy, wherein the solar cell module comprises: a floodlight panel with a light transmission property; solar cells each of which has a light-receiving surface with electrode pads and a non-light-receiving surface opposite to the light-receiving surface, the solar cells being adhered to the floodlight panel so that the light-receiving surface faces the floodlight panel; and a conductive bonding film which is interposed between the floodlight panel and the solar cells and bonds the floodlight panel to the solar cells, wherein the conductive bonding film is used to electrically connect the electrode pads of the solar cells adjacent to one another.

Also, the floodlight panel is exposed to the outside of the case, and includes a transparent glass through which external light is incident on the solar cells.

Also, the conductive bonding film has one end connected to a plus electrode pad of any one in solar cells, and the other end connected to a minus electrode pad of the other solar cell adjacent to the one solar cell.

Also, the device further includes a conductive spacer which is interposed between the floodlight panel and the solar cells and maintains intervals between the floodlight panel and the solar cells to be preset intervals.

In accordance with other aspect of the present invention to achieve the object, there is provided a method for manufacturing a solar cell module including the steps of: preparing a floodlight panel; coating a conductive paste on the floodlight panel; preparing solar cells each of which has a light-receiving surface with electrode pads and a non-light receiving surface opposite to the light-receiving surface; and bonding the floodlight panel to the solar cells by using the conductive paste as a bonding film while electrode pads of the solar cells adjacent to one another are interconnected by the conductive paste.

Also, the step of bonding the floodlight panel to the solar cells is made by using the conductive paste as an adhesive.

Also, the step of preparing the floodlight panel includes a step of preparing a transparent glass which has an exposure surface exposed to the outside, and a non-exposure surface facing the light-receiving surface of the solar cells, and the step of coating the conductive paste includes a step of forming a metal paste composition by restricting bonding regions from the non-exposure surface, the bonding regions being used for bonding of the solar cells to the floodlight panel by the conductive paste.

Also, the step of coating the conductive paste includes a step of forming a metal paste composition on the floodlight panel, the metal paste composition including at least one of Au, Ag, Ni, In, Zn, Ti, Cu, Cr, Ta, W, Pt, Fe, and Co.

Also, the step of coating the conductive paste includes a step of performing at least one of a silk screen process, a dispensing process, and an ink-jet coating process.

Also, the step of preparing the floodlight panel includes a step of preparing a transparent glass which has an exposure surface exposed to the outside, and a non-exposure surface facing the light-receiving surface of the solar cells, and the method for manufacturing the solar cell module further includes a step of forming a molding film for covering the non-exposure surface so that the solar cells can be made airtight.

Also, the method further includes a step of interposing a conductive spacer between the floodlight panel and the solar cells in such a manner that the floodlight panel and the solar cells are maintained to have preset intervals.

Also, the step of interposing the conductive spacer includes a step of bonding a stud bump to the electrode pads of the solar cells.

Also, the step of bonding the solar cells to the floodlight panel includes a step of relatively moving the floodlight panel and the solar cells in such a manner that the floodlight panel and the solar cells can be closely adhered to one another, the conductive pacer being used as a stopper for stopping relative movement of the floodlight panel and the solar cells.

Also, the step of preparing the floodlight panel includes a step of preparing a transparent glass which has bonding regions for bonding of the solar cells, and the step of bonding the solar cells to the floodlight panel includes a step of restricting a close adhesion distance between the floodlight panel and the solar cells so that the bonding regions are restricted as the conductive paste is spread by the close adhesion of the floodlight panel and the solar cells, and the step of restricting the close adhesion distance between the floodlight panel and the solar cells is made by controlling a thicknesses of the conductive spacer.

In accordance with other aspect of the present invention to achieve the object, there is provided a method for manufacturing a mobile device including the steps of: preparing a case with openings; forming a display unit, displaying information to the outside, in the case; and forming a solar cell module, receiving external light to convert the received external light into an electric energy, in the case, wherein the step of providing the solar cell module includes the steps of: preparing a floodlight panel; coating a conductive paste on the floodlight panel; preparing solar cells each of which has a light-receiving surface with electrode pads and a non-light receiving surface opposite to the light-receiving surface; bonding the floodlight panel to the solar cells by using the conductive paste as a bonding film while electrode pads of the solar cells adjacent to one another are interconnected by the conductive paste; and mounting the floodlight panel on the case so that the openings are made airtight by the floodlight panel.

Also, the method further includes a step of interposing a conductive spacer between the floodlight panel and the solar cells in such a manner that the floodlight panel and the solar cells are maintained to have preset intervals.

Also, the step of interposing the conductive spacer includes a step of bonding a stud bump to the electrode pads of the solar cells.

Also, the step of bonding the solar cells to the floodlight panel includes a step of relatively moving the floodlight panel and the solar cells in such a manner that the floodlight panel and the solar cells can be closely adhered to one another, the conductive pacer being used as a stopper for stopping relative movement of the floodlight panel and the solar cells.

Also, the step of preparing the floodlight panel includes a step of preparing a transparent glass which has bonding regions for bonding of the solar cells, and the step of bonding the solar cells to the floodlight panel includes a step of restricting a close adhesion distance between the floodlight panel and the solar cells so that the bonding regions are restricted as the conductive paste is spread by the close adhesion of the floodlight panel and the solar cells, and the step of restricting the close adhesion distance between the floodlight panel and the solar cells is made by controlling a thicknesses of the conductive spacer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view showing one example where a mobile device is equipped with a solar cell module in the prior art;

FIG. 2 is a view showing a solar cell module in accordance with an embodiment of the present invention;

FIG. 3 is a bottom view showing a front surface of the solar cell module shown in FIG. 2;

FIG. 4 is a plan view showing a rear surface of the solar cell module shown in FIG. 2;

FIG. 5 is a flowchart showing a method for manufacturing a solar cell module in accordance with an embodiment of the present invention;

FIGS. 6 and 8 are views showing a process of a solar cell module in accordance with an embodiment of the present invention, respectively;

FIG. 9 is a view showing a solar cell module in accordance with a modified embodiment of the present invention;

FIG. 10 is a flowchart showing a method for manufacturing a solar cell module in accordance with a modified embodiment of the present invention;

FIGS. 11 and 12 are views showing a process of manufacturing a solar cell module in accordance with a modified embodiment of the present invention, respectively; and

FIG. 13 is a view showing a mobile device in accordance with an embodiment of the present invention.

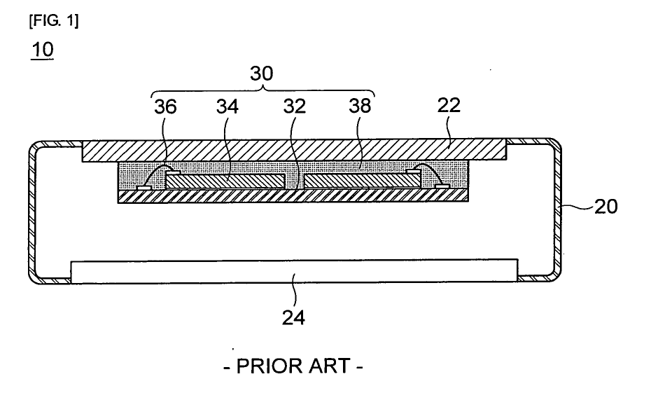

### DETAILED DESCRIPTION OF THE PREFERABLE EMBODIMENTS

The invention now will be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Hereinafter, a solar cell module, a mobile device with the solar cell module, and methods for manufacturing the solar cell module and the mobile device in accordance with an embodiment of the present invention will be described in more detail with reference to the accompanying drawings.

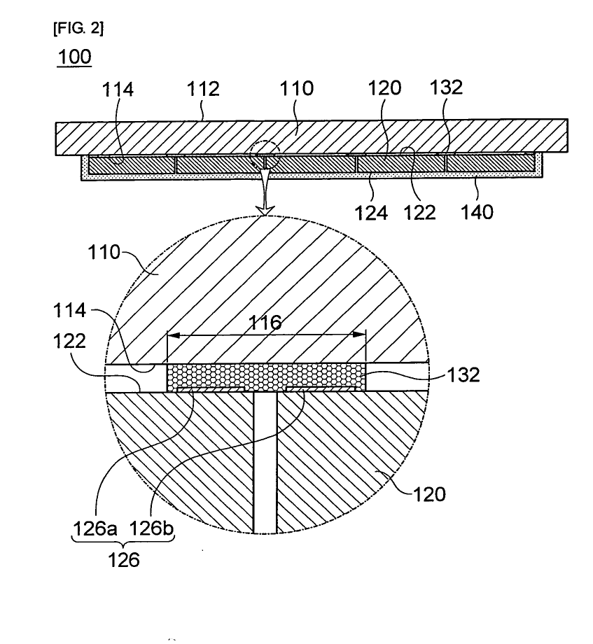

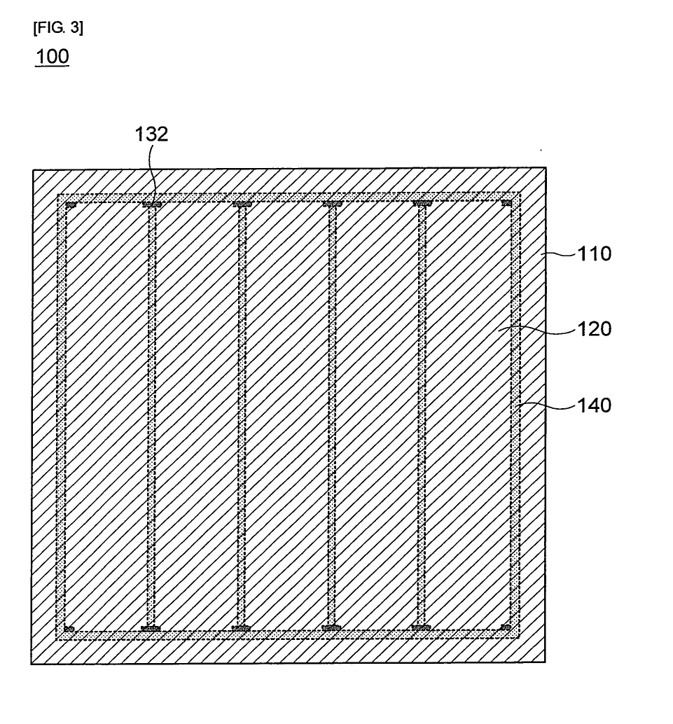

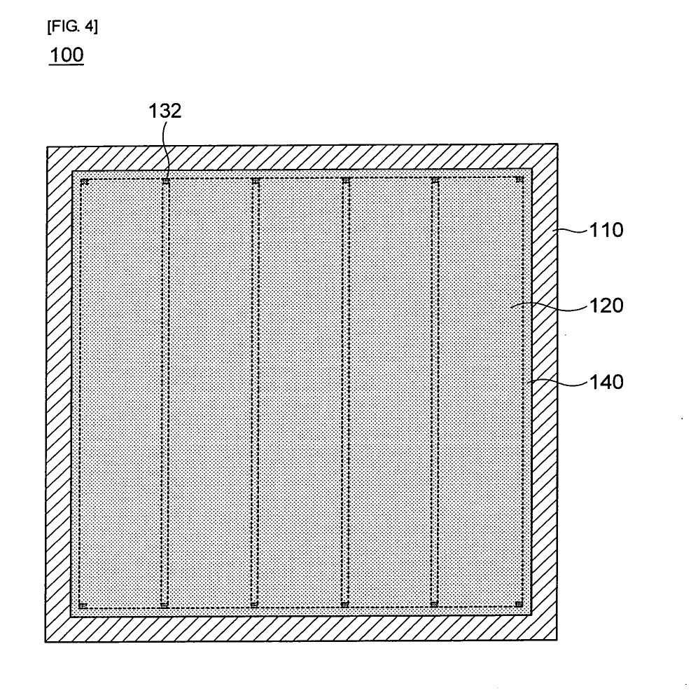

FIG. 2 is a view showing a solar cell module in accordance with the embodiment of the present invention. FIG. 3 is a bottom view showing a front surface of the solar cell module shown in FIG. 2. FIG. 4 is a plan view showing a rear surface of the solar cell module shown in FIG. 2.

Referring to FIGS. 2 to 4, the solar cell module 100 of the present invention may include a floodlight panel 110, elements of a solar cell 120 (hereinafter, referred to as “solar cells”), a conductive bonding film 132, and a molding film 140.

The floodlight panel 110 may be made of a light transmissive material. For one example, the floodlight panel 110 may include a transparent glass with a light transmissive property. The transparent glass may be a reinforced glass. When an electronic apparatus like a mobile device is to be equipped with the floodlight panel 110, the floodlight panel 110 may have an exposure surface 112 exposed to the outside and a non-exposure surface 114 opposite to the exposure surface 112. The floodlight panel 110 is exposed to the outside of the electronic apparatus, and it can protect the solar cell module 100 from an external environment, as well as play a role of a medium which allows external light to be incident on the solar cells 120.

Each of the solar cells 120 may have a light-receiving surface 122 and a non light-receiving surface 124. The light-receiving surface 122 may be a surface receiving incident light. The non light-receiving surface 124 may be a surface opposite to the light-receiving surface 122. The edge region of the light-receiving surface 122 may be provided with an electrode structure 126. The electrode structure 126 may include plus electrodes 126a and minus electrodes 126b. Herein, the solar cells 120 may be disposed in such a manner that the plus electrodes 126a and the minus electrodes 126b are alternately located to be adjacent to one another. In more particular, the solar cells 120 may be disposed in such a manner that a plus electrode of any one in the solar cells 120 is adjacent to a minus electrode of the other solar cell adjacent to the one solar cell. To this end, the solar cells 120 may be horizontally disposed so that the light-receiving surface 122 and the non light-receiving surface 124 are positioned on the same plane as each other.

The conductive bonding film 132 may electrically connect the solar cells 120 to one another. For example, the conductive bonding film 132 may interconnect the plus electrodes 126a and the minus electrodes 126b of the solar cells 120 adjacent to one another. To this end, one part of the conductive bonding film 132 may be connected to a plus electrode of any one in the solar cells, and the other part of the conductive bonding film 132 may be connected to a minus electrode of the other solar cell adjacent to the one. Thus, the solar cells 120 may be connected in series to one another by the conductive bonding film 132.

In addition to this, the conductive bonding film 132 may allow the floodlight panel 110 to be bonded to the solar cells 120. For example, the conductive bonding film 132 may be used as a bonding film for bonding the floodlight panel 110 to the solar cells 120. The floodlight panel 110 may have bonding regions 116 provided as bonding spacing of the solar cells 120. Each of the bonding regions 116 may be where the conductive bonding film 132 is formed, so it may be advantageous to locate bonding regions at positions where the light-receiving surfaces of the solar cells are shielded as little as possible so as to improve light-incident rates. Thus, it is preferable to minimize regions for formation of the conductive bonding film 132 under the condition where the floodlight panel 110 and the solar cells 120 are kept enough bonded between them. Also, each of the bonding regions 116 may be a region only for the formation of the conductive bonding film 132 by which the plus electrodes 126a to the minus electrodes 126b can be electrically interconnected.

As such, the conductive bonding film 132 may be used as not only a conductive pattern for electrical connection of the plus electrodes 126a and the minus electrodes 126b, but also an adhesion film for bonding the floodlight panel 110 to the solar cells 120. Thus, the conductive bonding film 132 may be formed of a material capable of enough performing the functions. For example, the conductive bonding film 132 may include a material with an electric conductivity required for effectively electrical connection of the plus electrodes 126a and the minus electrodes 126b. For one example, the conductive bonding film 132 may include at least one of Au, Ag, Ni, In, Zn, Ti, Cu, Cr, Ta, W, Pt, Fe, and Co. In addition to this, the conductive bonding film 132 may further include a material with an adhesive force enough to perform a function as the adhesion film. For example, the conductive bonding film 132 may further include a material of acryl resin and epoxy resin. Herein, there is a possibility of reducing an electric conductivity of the conductive bonding film 132 by a resin material, so it is preferable to contain the resin material in the conductive bonding film 132 as small as possible.

The molding film 140 is for protecting the solar cells 120 and the conductive bonding film 132. For example, the molding film 140 may cover the non-exposure surface 114 of the floodlight panel 110 in such a manner that the solar cells 120 are made airtight. By the molding film 140, the solar cells 120 and the conductive bonding film 132 may be airtight and protected from the external environment. Meanwhile, the molding film 140 is provided on the non light-receiving surface 124 of the solar cells 120, so there is no need to provide the molding film 140 as a component to transmit light from the outside. Thus, the molding film 140 may be formed of an opaque epoxy resin.

As described above, the solar cell module 100 of the present invention may be made by bonding the solar cells 120 to the floodlight panel 110 through interposition of the conductive bonding film 132. Thus, the solar cell module 100 may have a structure where intervals between the floodlight panel 110 and the solar cells 120 are minimized to thereby increase a degree of integration.

The solar cell module 100 may have a structure where the plus electrodes 126a and the minus electrodes 126b of the solar cells 120 are electrically connected to one another by using the conductive bonding film 132. Thus, the solar cell module 100 may have a more improved degree of integration by minimizing installation spaces provided as regions where the plus electrodes 126a and the minus electrodes 126b are electrically connected to one another, in comparison with bonding wires in the prior art.

The solar cell module 100 may be structured to have the light-receiving surface 122 of the solar cells 120 closely adhered to be bonded to the floodlight panel 110, so that it is possible to increase incident rates of light on the solar cells 120. Therefore, it is possible to implement a solar cell module with a higher efficiency.

Also, the solar cell module 100 may have a structure where the plus electrodes 126a and the minus electrodes 126b are electrically connected to one another by the conductive bonding film 132 which bonds the floodlight panel 110 to the solar cells 120, so that there is no need to provide a separate circuit substrate. Therefore, it is possible to reduce manufacture's cost, and to implement a simpler configuration than a solar cell module with a PCB.

Continuously, a detailed description will be given of a method for manufacturing a solar cell module in accordance with the embodiment of the present invention. Herein, the repeated description thereof will be omitted or simplified.

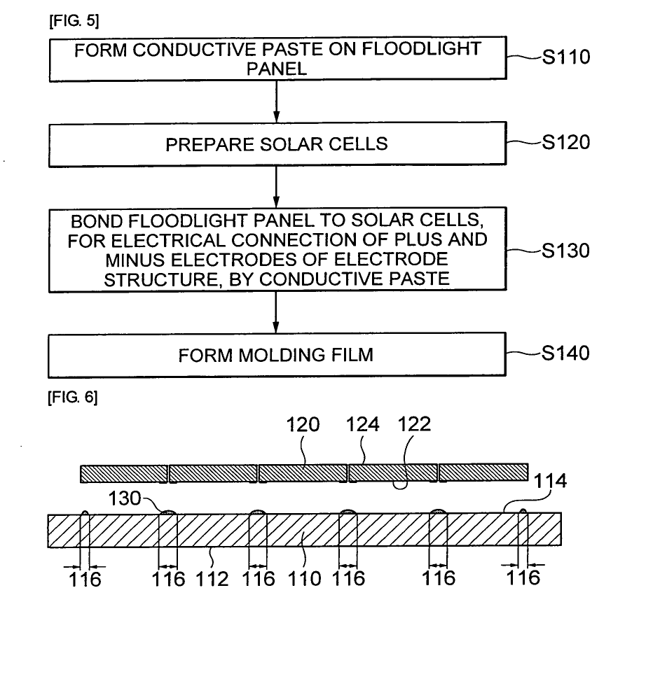

FIG. 5 is a flowchart showing a method for manufacturing a solar cell module in accordance with the embodiment of the present invention. FIGS. 6 to 8 are views showing a process of manufacturing a solar cell module in accordance with the embodiment of the present invention, respectively.

Referring to FIGS. 5 and 6, a conductive paste 130 may be formed on the floodlight panel 110 (step S110). For example, the floodlight panel 110 with the exposure surface 112 and the non-exposure surface 114 may be prepared. Each of the bonding regions 116 for bonding of the solar cells (indicated by reference numeral 120 of FIG. 7) may be provided on the non-exposure surface 114 at the time of a subsequent process. The conductive paste 130 may be coated selectively on the bonding regions 116 of the floodlight panel 110. The step of coating the conductive paste may be performed by using a silk screen process, a dispensing process, an ink-jet coating process, and so on. As for the conductive paste, liquid paste composition containing at least one of Au, Ag, Ni, In, Zn, Ti, Cu, Cr, Ta, W, Pt, Fe, and Co may be used.

Meanwhile, the amount of the conductive paste to be coated may be controlled in consideration of the fact that the conductive paste is widely spread into a thin film when the floodlight panel 110 is closely adhered to the solar cells 120 at the time of a subsequent process. Thus, the amount of the conductive paste to be coated on the floodlight panel 110 may be controlled to be suited to each of the bonding regions 116 when the floodlight panel 110 is closely adhered to the solar cells 120.

And, the solar cells 120 may be prepared (step S120). The step of preparing the solar cells 120 may include a step of manufacturing the solar cells 120 each of which includes the light-receiving surface 122 for receiving external light through the floodlight panel 110 and the non light-receiving surface 124 opposite to the light-receiving surface 122.

Referring to FIGS. 5 and 7, the floodlight panel 110 and the solar cells 120 may be bonded to one another in such a manner that the plus electrodes 126a and the minus electrodes 126b of the electrode structure 126 can be electrically connected to one another by the conductive paste, indicated by reference numeral 130 of FIG. 6 (step S120). For example, the solar cells 120 may be disposed in such a manner that a plus electrode of any one in the solar cells 120 is adjacent to a minus electrode of the other solar cell in the solar cells 120. And, the solar cells 120 may be closely adhered to the floodlight panel 110 while the plus electrodes 126a and the minus electrodes 126b are interconnected by the conductive paste.

Meanwhile, the conductive paste 130 may be made into a thin film as the floodlight panel 110 and the solar cells 120 are adhered to one another. In this case, the coating amount of the conductive paste 130 may be controlled in such a manner that the conductive paste 130 is formed into the conductive bonding film 132 only at each of the bonding regions 116. Thus, there may be formed the conductive bonding film 132 at the bonding regions 116 as the floodlight panel 110 is bonded to the solar cells 120, the conductive bonding film 132 being electrically connecting the plus and minus electrodes 126a and 126b adjacent to one another. By the conductive bonding film 132, the solar cells 120 are electrically interconnected in series and adhered to the floodlight panel 110.

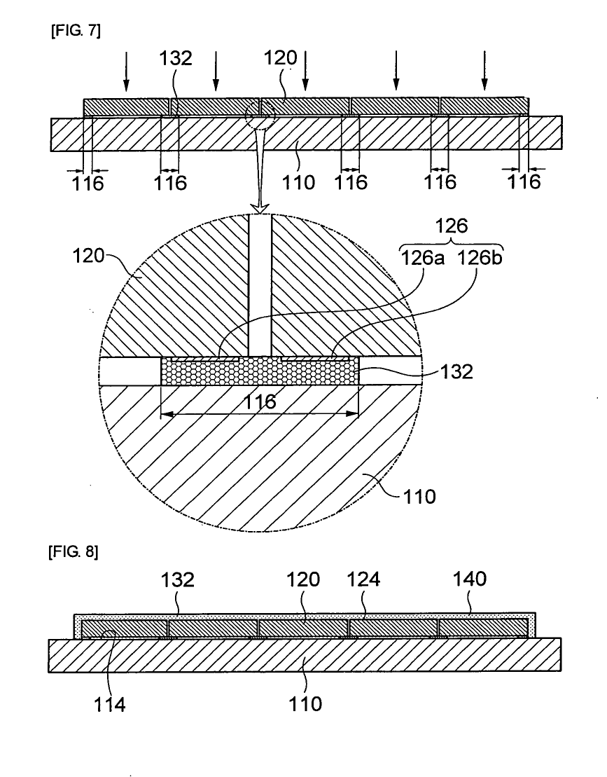

Referring to FIGS. 5 and 8, the molding film 140 may be formed (step S130). The step of forming the molding film 140 may include a step of forming an insulating film on the non-exposure surface 114 of the floodlight panel 110 in such a manner that the solar cells 120 can be made airtight from the external environment. Thus, there may be formed the molding film 140 for protecting the solar cells 120 and the conductive bonding film 132 from the external environment. In this case, the molding film 140 is formed to cover the non light-receiving surface 124 of the solar cells 120, so there is no need to provide the molding film 140 as a light-transmissive film taking a relatively high cost. Thus, a resin-based material like epoxy resin may be used as the insulating film.

As described above, according to the method for manufacturing the solar cell module of the present invention, it is possible to manufacture the solar cell module 100 where the solar cells 120 are adhered to the floodlight panel 110 by the conductive bonding film 132 interposed therebetween. Thus, in the method for manufacturing the solar cell module of the present invention, it is possible to minimize intervals between the floodlight panel 110 and the solar cells 120, thereby manufacturing the solar cell module 100 with the improved degree of integration.

Also, according to the method for manufacturing the solar cell module, the plus electrodes 126a and the minus electrodes 126b of the solar cells 120 can be connected to one another by the conductive bonding film 132 which bonds the floodlight panel 110 to the solar cells 120. Thus, in the method for manufacturing the solar cell module, it is possible to implement the solar cell module 100 with a higher degree of integration than a solar cell module with a configuration of connected electrodes by bonding wires. In addition to this, according to the method for manufacturing the solar cell module, it is possible to manufacture a solar cell module 100 even without a separate circuit substrate like a PCB, which results in a decrease in manufacture's cost and simplification of manufacturing's process.

Hereinafter, a detailed description will be given of a solar cell module and a method for manufacturing the solar cell module according to the present invention. Herein, the repeated description thereof will be omitted and simplified.

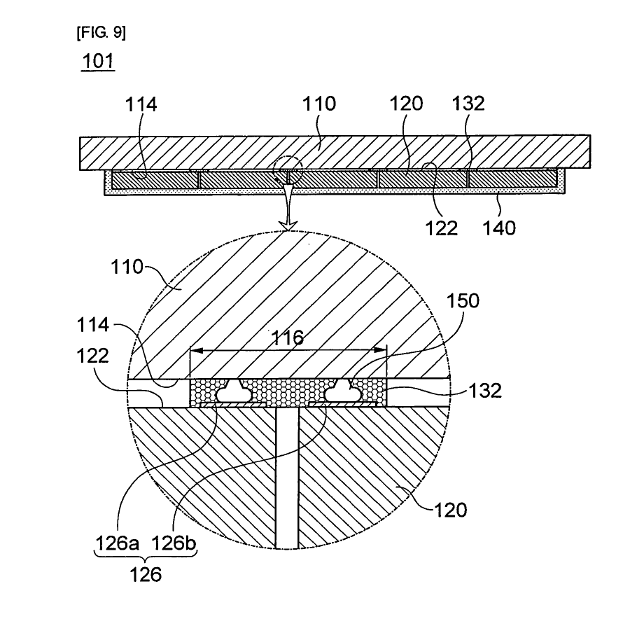

FIG. 9 is a view showing a solar cell module according to a modified embodiment of the present invention. In more particular, FIG. 9 may be a view showing one modified example of the solar cell module 100 described in FIG. 2.

Referring to FIG. 9, the solar cell module 101 according to the modified embodiment of the present invention may more include a conductive spacer 150 than the solar cell module 100 described in FIG. 2. For example, the solar cell module 101 may include the floodlight panel 110 and the solar cells 120 bonded to one another by the conductive bonding film 132, the molding film 140 for molding the solar cells 120, and the conductive spacer 150 interposed between the floodlight panel 110 and the solar cells 120.

The conductive spacer 150 may be disposed only at the bonding region 116 of the non-exposure surface 114 of the floodlight panel 110. The thickness of the conductive spacer 150 may be formed to have the same size as preset intervals between the floodlight panel 110 and the third recess 129. Thus, the floodlight panel 110 and the solar cells 120 may be disposed to be spaced apart from one another at a thickness of the conductive spacer 150.

Also, the conductive spacer 150 may reinforce electrical connection of the electrode structure 126 in the solar cells 120 adjacent to one another by the conductive bonding film 132. For example, the conductive bonding film 132 may be formed of a certain conductive paste, so the conductive bonding film 132 may have a relatively low electrical conductivity. Thus, the conductive spacer 150 may be formed of metallic material with a low electrical resistance so as to reinforce a low electrical conductivity of the conductive bonding film 132. To this end, as for the conductive spacer 150, various types of bumps with high electrical conductivities may be used. For one example, as for the conductive spacer 150, a stud bump may be used. In this case, the stud bump may be bonded to the plus electrodes 126a and the minus electrodes 126b of the electrode structure 126.

Meanwhile, the conductive spacer 150 may be formed of a metallic material containing at least one of Au, Ag, Ni, In, Zn, Ti, Cu, Cr, Ta, W, Pt, Fe, and Co. In this case, the conductive spacer 150 may be formed of the same material as that of the conductive bonding film 132. Also, the conductive spacer 150 may be formed of a material having a relatively higher electrical conductivity than that of the conductive bonding film 132.

As described above, in the solar cell module 100 according to a modified embodiment of the present invention, the floodlight panel 110 is bonded directly to the solar cells 120 by the conductive bonding film 132 interposed therebetween, and the floodlight panel 110 and the solar cells 120 are disposed to be spaced apart from one another at a predetermined interval by the conductive spacer 150. Thus, the solar cell module 101 of the present invention may have a structure where the floodlight panel 110 and the solar cells 120 are boned to one another while being spaced apart from one another at a predetermined interval.

Also, the solar cell module 101 may further include the conductive spacer 150 for reinforcing electrical connection of the conductive bonding film 132 by which the plus electrodes 126a and the minus electrodes 126b of the solar cells 120 can be interconnected. Thus, according to the solar cell module 101 of the present invention, it is possible to improve a degree of integration by minimizing intervals between the solar cells 120 and floodlight panel 110, as well as to increase electrical bonding reliability of the plus electrodes 126a and the minus electrodes 126b.

Continuously, a detailed description will be given of a method for manufacturing the solar cell module according to the modified embodiment of the present invention. Herein, the repeated description thereof will be omitted or simplified.

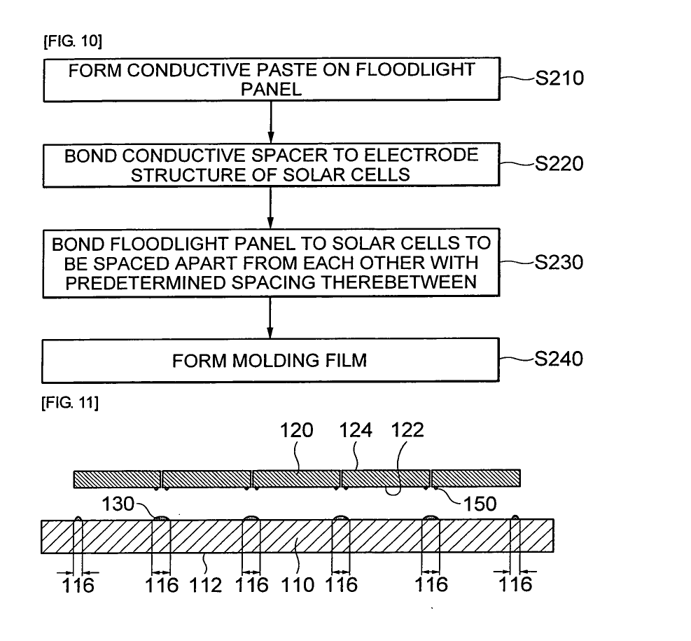

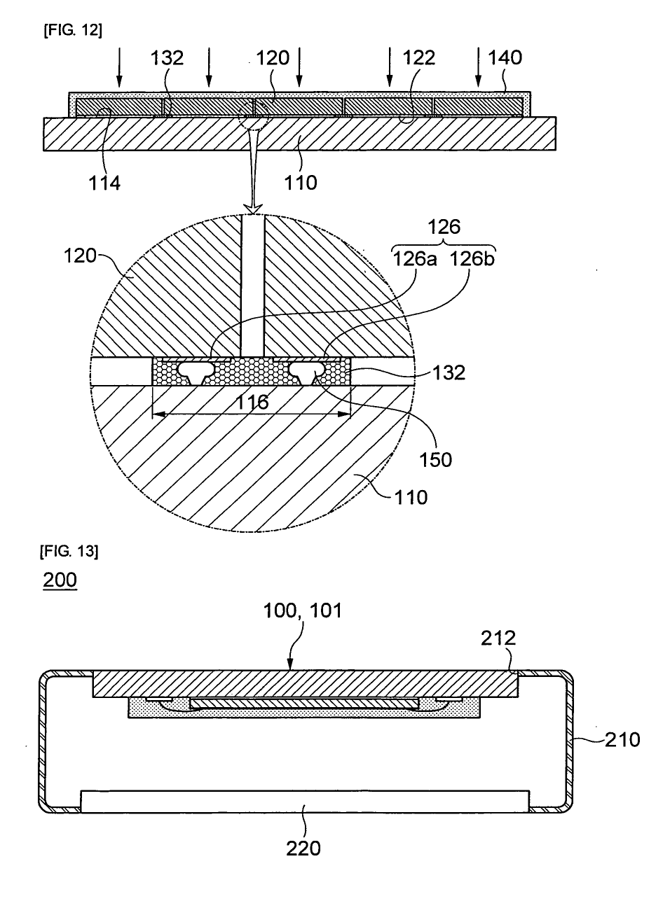

FIG. 10 is a flowchart showing a method for manufacturing the solar cell module according to the modified embodiment of the present invention. FIGS. 11 and 12 are views showing a process of manufacturing the solar cell module according to the modified embodiment of the present invention, respectively.

Referring to FIGS. 10 and 11, the conductive paste 130 may be formed on the floodlight panel 110 (step S210). For example, the conductive paste 130 may be coated selectively on the bonding regions 116. The step of coating the conductive paste may be performed by using a silk screen process, a dispensing process, an ink-jet coating process, and so on.

The conductive spacer 150 may be bonded to the electrode structure 126 of the solar cells 120 (step S220). For example, there may be included a step of preparing the conductive bump. For one example, the stud bump may be prepared. The stud bump may be formed of a material including at least one of Au, Ag, Ni, In, Zn, Ti, Cu, Cr, Ta, W, Pt, Fe, and Co.

The plus electrodes 126a and the minus electrodes 126b of the solar cells 120 may be bonded to the conductive spacer 150 (step S220). For example, the step of bonding the conductive spacer 150 may include a step of positioning the stud bump on each of the plus electrodes 126a and the minus electrodes 126b, and a step of performing a heat-treatment process for the stud bump. Thus, the conductive spacer 150 may be bonded to each of the plus electrodes 126a and the minus electrodes 126b of the solar cells 120.

Referring to FIGS. 10 and 12, the floodlight panel 110 may be bonded to the solar cells 120 while meeting the interval between the floodlight panel 110 and the solar cells 120 to be a preset interval (step S230). For example, the floodlight panel 110 and the solar cells 120 may be disposed in such a manner that the non-exposure surface 114 of the floodlight panel 110 faces the light-receiving surface 122 of the solar cells 120. In this case, the floodlight panel 110 and the solar cells 120 may be arranged in such a manner that the conductive spacer 150 faces the bonding regions 116 of the floodlight panel 110.

And, the floodlight panel 110 may be closely adhered to the solar cells 120 in such a manner that the plus electrodes 126a and the minus electrodes 126b are electrically connected by the conductive paste (indicated by reference numeral 130 of FIG. 11). In the course of this process, the conductive paste 130 may make the floodlight panel 110 and the solar cells 120 to be bonded to one another as it is formed into the conductive bonding film 132 for electrical connection of the plus electrodes 126a and the minus electrodes 126b.

Herein, the step of bonding the floodlight panel 110 to the solar cells 120 may include a step of restricting a close adhesion distance between the floodlight panel 110 and the solar cells 120 in such a manner that the conductive paste 130 is widely spread only to the bonding regions 16 as the floodlight panel 110 comes into close contact to the solar cells 120. The step of restricting the close adhesion distance between the floodlight panel 110 and the solar cells 120 may be made by the conductor spacer 150. That is, in the course of close contact between the solar cells 120 and the floodlight panel 110, the conductive spacer 150 may be used as a stopper for stopping a relative movement of the floodlight panel 110 and the solar cells 120.

Meanwhile, in the course of bonding the floodlight panel 110 to the solar cells 120, a step of heat-treating the conductive spacer 150 may be additionally performed. The step of heat-treating the conductive spacer 150 may include a step of performing a reflow process for the stud bump. Thus, the conductive spacer 150 may be used as a spacer for maintaining the intervals between the floodlight panel 110 and the solar cells 120. The conductive spacer 150 finally formed by the heat-treatment process may have the same thickness as the preset intervals between the floodlight panel 110 and the solar cells 120. Thus, during the processes described above, the conductive spacer 150 may be prepared in consideration of change in a thickness of the conductive spacer.

Thereafter, the molding film 140 may be formed (step S240). The step of forming the molding film 140 may include a step of forming an insulating film on the non-exposure surface 114 of the floodlight panel 110 in such a manner that the solar cells 120 can be made airtight from the external environment. As for the insulating film, a resin-based material like epoxy resin may be used.

As described above, according to the method for manufacturing the solar cell module of the embodiment of the present invention, the conductive bonding film 132 in a thin film shape is used as an adhesion film, so as to adhere the floodlight panel 110 on the solar cells 120 to thereby manufacture the solar cell module 100. Also, by proving the conductive spacer 150 between the floodlight panel 110 and the solar cells 120, so that it is possible to bond the floodlight panel 110 to the solar cells 120 at a predetermined interval. Thus, according to the method for manufacturing the solar cell module of the present invention, it is possible to bond the floodlight panel 110 to the solar cells 120 through control of a preset interval therebetween.

Also, according to the method for manufacturing the solar cell module of the present invention, the plus electrodes 126a and the minus electrodes 126b of the solar cells 120 are connected to one another by the conductive bonding film 132, and the conductive spacer 150 for reinforcing the electrical conductivity of the conductive bonding film 132 may be formed. Thus, according to the method for manufacturing the solar cell module of the present invention, it is possible to increase bonding reliability between the floodlight panel 110 and the solar cells 120, as well as to improve electrical connection reliability between the plus electrodes 126a and the minus electrodes 126b of the solar cells 120.

Hereinafter, a detailed description will be given of a mobile device and a method for manufacturing the mobile device according to the embodiment of the present invention. Herein, the repeated description thereof will be omitted or simplified.

FIG. 13 is a view showing a mobile device equipped with the solar cell module in accordance with an embodiment of the present invention. Referring to FIG. 13, the mobile device 200 may include a display unit 220 for displaying image to the outside, and a case 200 which is equipped selectively with one of the above-mentioned solar cell modules 100 and 101.

One side of the case 210 may be provided with openings 212 for installation of the solar cell modules 100 and 101. For example, the openings 212 are for fixedly mounting the floodlight panel 110 of the solar cell modules 100 and 101. That is, the openings 212 are made airtight by the floodlight panel 110 of the solar cell modules 100 and 101, and thus the solar cell modules 100 and 101 may be mounted on the mobile device 200. In this case, the floodlight panel 110 is exposed to the outside, and the external light may be incident on the solar cells 120 through the floodlight panel 110. Herein, since the floodlight panel 110 is exposed to the outside, the floodlight panel 110 may have rigidity enough to protect the solar cell modules 100 and 101 form the external shock. In addition to this, the floodlight panel 110 may allow light to be incident on the solar cells 120 while meeting the least light-loss of the external light.

The display unit 220 may be disposed on the other side of the case 210. The display unit 220 may be a component for displaying electron information to the outside for user's recognition. To this end, the display unit 220 may include any one of various flat panel display elements.

The mobile device 200 with the above-described structure may be provided with the solar cell modules 100 and 101 which include a case 210 with the openings 212 through which light is incident, and the floodlight panel 110 for sealing the opening 212. Thus, in the mobile device 200 of the present invention, the floodlight panel 110 is mounted directly on the case 210 of the mobile device 200, so as to use the floodlight panel 110 as a protective film for protecting the mobile device from the external environment. Therefore, the solar cell modules 100 and 101 alone are used to manufacture the mobile device 200 even without a separate reinforced glass.

Meanwhile, a description will be given of one example of a method for manufacturing the mobile device 200. The method for manufacturing the mobile device may include a step of preparing the case 210 with the openings 212, a step of preparing the solar cell modules 100 and 101 with the solar cells 120 adhered to the floodlight panel 110 by the transparent adhesive film 130 interposed therebetween, and a step of proving the openings 212 on the solar cell modules 100 and 101 formed in the case 210 in such a manner that the openings 212 are made airtight by the floodlight panel 110. Thus, according to the method for manufacturing the mobile device, it is possible to implement a higher degree of integration and manufacturing efficiency of the mobile device 200 by directly mounting the floodlight panel 110 on the case 210 so as to use the floodlight panel 110 as a protective film from the external environment. According to the present invention, a solar cell module and a mobile device with the solar cell module may have a structure where an interposed conductive bonding film of a thin film shape is provided so that solar cells are bonded directly to a floodlight panel. Thus, in the solar cell module and a mobile device with the solar cell module of the present invention, it is possible to minimize intervals between the solar cells and the floodlight panel, which results in improvement of a degree of integration.

In a solar cell module and a mobile device according to the present invention, a conductive bonding film of a thin film shape is used to electrically interconnect plus electrodes and minus electrodes of solar cells.

Thus, when compared with a configuration formed by bonding wires, the solar cell module and the mobile device with the solar cell module of the present invention have advantages in that installation spaces for components required for electrical connection of the electrodes are minimized to thereby improve a degree of its integration.

In the method for manufacturing the solar cell module of the present invention, solar cells are adhered on a floodlight panel by a conductive bonding film in a thin film shape interposed therebetween, so that it is possible to a solar cell module.

Thus, in the method for manufacturing the solar cell module of the present invention, it is possible to provide a solar cell module with a higher degree of integration by minimization of intervals between the floodlight panel and the solar cells.

In the method for manufacturing the solar cell module of the present invention, plus electrodes and minus electrodes of solar cells can be interconnected to one another by a conductive bonding film used for bonding a floodlight panel and the solar cells.

Thus, according to the method for manufacturing the solar cell module, it is possible to manufacture a solar cell module with an improved degree of integration in comparison with a configuration made by bonding wires.

In the method for manufacturing a mobile device according to the present invention, it is possible to manufacture a solar cell module by adhesion of solar cells to a floodlight panel through a conductive bonding film of a thin film interposed therebetween. Therefore, it is possible to mount the manufacture solar cell module on openings of its case. Thus, in the method for manufacturing a mobile device according to the present invention, it is possible to minimize intervals between the floodlight panel and solar cells, thereby manufacturing a mobile device equipped with a solar cell module with an improved degree of integration.

In the method for manufacturing a solar cell module according to the present invention, the solar cell module may be manufactured with a structure where plus and minus electrodes of solar cells are interconnected by a conductive bonding film used for bonding the floodlight panel and solar cells, and the manufactured solar cell module may be mounted on openings of its case. Thus, in the method for manufacturing the solar cell module, it is possible to manufacture a mobile device equipped with a solar cell module with an improved degree of integration, in comparison with a case where electrodes are connected to one another by bonding wires.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A solar cell module comprising:
a floodlight panel with a light transmission property;
solar cells each of which has a light-receiving surface with electrode pads and a non-light-receiving surface opposite to the light-receiving surface, the solar cells being adhered to the floodlight panel so that the light-receiving surface faces the floodlight panel; and
a conductive bonding film which is interposed between the floodlight panel and the solar cells and bonds the floodlight panel to the solar cells,
wherein the conductive bonding film is used to electrically connect the electrode pads of the solar cells adjacent to one another.

2. The module of claim 1, wherein the conductive bonding film is formed by coating a metal paste composition on the floodlight panel.

3. The module of claim 1, wherein the conductive bonding film corresponds to a metal film including at least one of Au, Ag, Ni, In, Zn, Ti, Cu, Cr, Ta, W, Pt, Fe, and Co.

4. The module of claim 1, wherein the conductive bonding has one end connected to a plus electrode pad of any one in solar cells, and the other end connected to a minus electrode pad of the other solar cell adjacent to the one solar cell.

5. The module of claim 1, wherein the floodlight panel has an exposure surface exposed to the outside, and a non-exposure surface facing the light-receiving surface of the solar cells, and the solar cell module further includes a molding film for covering the non-exposure surface so that the solar cells can be made airtight.

6. The module of claim 5, wherein the molding film is formed of an opaque material.

7. The module of claim 1, further comprising a conductive spacer which is interposed between the floodlight panel and the solar cells and maintains intervals between the floodlight panel and the solar cells to be preset intervals.

8. The module of claim 7, wherein the conductive module is bonded to the electrode pads.

9. The module of claim 8, wherein the conductive spacer is made of at least one metal of Au, Ag, Ni, In, Zn, Ti, Cu, Cr, Ta, W, Pt, Fe, and Co.

10. The module of claim 8, wherein the conductive spacer further includes a stud bump.

11. A mobile device comprising:
a case which has one side with openings;
a display unit which is formed on the other side of the case and displays information to the outside; and
a solar cell module which is embedded in the case and receives external light to convert the received external light into an electric energy,
wherein the solar cell module comprises:
a floodlight panel with a light transmission property;
solar cells each of which has a light-receiving surface with electrode pads and a non-light-receiving surface opposite to the light-receiving surface, the solar cells being adhered to the floodlight panel so that the light-receiving surface faces the floodlight panel; and
a conductive bonding film which is interposed between the floodlight panel and the solar cells and bonds the floodlight panel to the solar cells,
wherein the conductive bonding film is used to electrically connect the electrode pads of the solar cells adjacent to one another.

12. The device of claim 11, wherein the floodlight panel is exposed to the outside of the case, and includes a transparent glass through which external light is incident on the solar cells.

13. The device of claim 11, wherein the conductive bonding film has one end connected to a plus electrode pad of any one in solar cells, and the other end connected to a minus electrode pad of the other solar cell adjacent to the one solar cell.

14. The device of claim 11, further comprising a conductive spacer which is interposed between the floodlight panel and the solar cells and maintains intervals between the floodlight panel and the solar cells to be preset intervals.

15. A method for manufacturing a solar cell module comprising:
preparing a floodlight panel;
coating a conductive paste on the floodlight panel;
preparing solar cells each of which has a light-receiving surface with electrode pads and a non-light receiving surface opposite to the light-receiving surface; and
bonding the floodlight panel to the solar cells by using the conductive paste as a bonding film while electrode pads of the solar cells adjacent to one another are interconnected by the conductive paste.

16. The method of claim 15, wherein bonding the floodlight panel to the solar cells is made by using the conductive paste as an adhesive.

17. The method of claim 15, wherein preparing the floodlight panel includes preparing a transparent glass which has an exposure surface exposed to the outside, and a non-exposure surface facing the light-receiving surface of the solar cells, and coating the conductive paste comprises forming a metal paste composition by restricting bonding regions from the non-exposure surface, the bonding regions being used for bonding of the solar cells to the floodlight panel by the conductive paste.

18. The method of claim 15, wherein coating the conductive paste comprises forming a metal paste composition on the floodlight panel, the metal paste composition including at least one of Au, Ag, Ni, In, Zn, Ti, Cu, Cr, Ta, W, Pt, Fe, and Co.

19. The method of claim 15, wherein coating the conductive paste comprises performing at least one of a silk screen process, a dispensing process, and an ink-jet coating process.

20. The method of claim 15, wherein preparing the floodlight panel comprises preparing a transparent glass which has an exposure surface exposed to the outside, and a non-exposure surface facing the light-receiving surface of the solar cells, and the method for manufacturing the solar cell module further comprises forming a molding film for covering the non-exposure surface so that the solar cells can be made airtight.

21. The method of claim 15, further comprising interposing a conductive spacer between the floodlight panel and the solar cells in such a manner that the floodlight panel and the solar cells are maintained to have preset intervals.

22. The method of claim 21, wherein interposing the conductive spacer comprises bonding a stud bump to the electrode pads of the solar cells.

23. The method of claim 21, wherein bonding the solar cells to the floodlight panel comprises relatively moving the floodlight panel and the solar cells in such a manner that the floodlight panel and the solar cells can be closely adhered to one another, the conductive pacer being used as a stopper for stopping relative movement of the floodlight panel and the solar cells.

24. The method of claim 21, wherein preparing the floodlight panel comprises preparing a transparent glass which has bonding regions for bonding of the solar cells, and bonding the solar cells to the floodlight panel comprises restricting a close adhesion distance between the floodlight panel and the solar cells so that the bonding regions are restricted as the conductive paste is spread by the close adhesion of the floodlight panel and the solar cells, and restricting the close adhesion distance between the floodlight panel and the solar cells is made by controlling a thicknesses of the conductive spacer.

25. A method for manufacturing a mobile device comprising:
preparing a case with openings;
forming a display unit, displaying information to the outside, in the case; and
forming a solar cell module, receiving external light to convert the received external light into an electric energy, in the case,
wherein providing the solar cell module comprises:
preparing a floodlight panel;
coating a conductive paste on the floodlight panel;
preparing solar cells each of which has a light-receiving surface with electrode pads and a non-light receiving surface opposite to the light-receiving surface;
bonding the floodlight panel to the solar cells by using the conductive paste as a bonding film while electrode pads of the solar cells adjacent to one another are interconnected by the conductive paste; and
mounting the floodlight panel on the case so that the openings are made airtight by the floodlight panel.

26. The method of claim 25, further comprising interposing a conductive spacer between the floodlight panel and the solar cells in such a manner that the floodlight panel and the solar cells are maintained to have preset intervals.

27. The method of claim 26, wherein interposing the conductive spacer comprises bonding a stud bump to the electrode pads of the solar cells.

28. The method of claim 25, wherein bonding the solar cells to the floodlight panel comprises relatively moving the floodlight panel and the solar cells in such a manner that the floodlight panel and the solar cells can be closely adhered to one another, the conductive pacer being used as a stopper for stopping relative movement of the floodlight panel and the solar cells.

29. The method of claim 28, wherein preparing the floodlight panel comprises preparing a transparent glass which has bonding regions for bonding of the solar cells, and bonding the solar cells to the floodlight panel comprises restricting a close adhesion distance between the floodlight panel and the solar cells so that the bonding regions are restricted as the conductive paste is spread by the close adhesion of the floodlight panel and the solar cells, and restricting the close adhesion distance between the floodlight panel and the solar cells is made by controlling a thicknesses of the conductive spacer.
